(19) United States
(12) Patent Application Publication
(10) Pub. No.: US 2015/0187542 A1
(43) Pub. Date: Jul. 2, 2015

(54) SUBSTRATE PROCESSING APPARATUS, SHUTTER DEVICE AND PLASMA PROCESSING APPARATUS

(71) Applicant: Tokyo Electron Limited, Tokyo (JP)

(72) Inventor: Toshifumi Ishida, Kurokawa-gun (JP)

(21) Appl. No.: 14/580,657

(22) Filed: Dec. 23, 2014

(30) Foreign Application Priority Data
Dec. 27, 2013 (JP) 2013-271617

(51) Int. Cl. H01J 37/32

(52) U.S. Cl. CPC H01J 37/32513; H01J 37/32495; H01J 2237/334; H01J 2237/0206

(57) ABSTRACT

Abnormal discharge is suppressed from occurring within a chamber. A plasma processing apparatus 1 includes a cylindrical chamber 10 having an opening 51 through which a processing target substrate is loaded into the chamber; a deposition shield 71 which is provided along an inner wall of the chamber 10 and has an opening 71a at a position corresponding to the opening 51; and a shutter 55, having a plate shape, configured to open and close the opening 71a. Further, in a state that the opening 71a is closed by the shutter 55, an outer periphery of the shutter 55 is overlapped with the deposition shield 71 in a thickness direction of the shutter 55 and an inner periphery of the opening 71a is overlapped with the shutter 55 in the thickness direction of the shutter 55.

### CROSS-REFERENCE TO RELATED APPLICATION

This application claims the benefit of Japanese Patent Application No. 2013-271617 filed on Dec. 27, 2013, the entire disclosures of which are incorporated herein by reference.

### TECHNICAL FIELD

The embodiments described herein pertain generally to a substrate processing apparatus, a shutter device, and a plasma processing apparatus.

### BACKGROUND

Conventionally, there is known a plasma processing apparatus that performs a certain plasma process on a wafer which is used as a processing target substrate for a semiconductor device. The plasma processing apparatus includes a chamber that accommodates therein, for example, a wafer. Within the chamber, there are provided a mounting table (hereinafter, referred to as “susceptor”) that mounts thereon the wafer and serves as a lower electrode; and an upper electrode facing the susceptor. A high frequency power supply is connected to at least one of the mounting table and the upper electrode, and at least one of the mounting table and the upper electrode applies a high frequency power to a space within the processing chamber.

In the plasma processing apparatus, ions or the like are generated by exciting a processing gas supplied into the space within the chamber into plasma by the high frequency power, and a required plasma process such as an etching process is performed on the wafer by guiding the generated ions or the like on the wafer W.

At a sidewall of the chamber, an opening for loading/unloading a semiconductor wafer is formed, and a gate valve that opens and closes the opening is provided. The semiconductor wafer is loaded into and unloaded from the chamber through the opening opened by the gate valve. Within the chamber, a deposition shield that suppresses adhesion of etching byproducts (deposits) is provided along an inner wall of the chamber, and the deposition shied is also provided with an opening at a position corresponding to the opening of the chamber.

Since the gate valve is provided outside the chamber (at the atmospheric side), there is formed a space protruded outward from the opening. If the plasma generated within the chamber diffuses up to that space of the opening, uniformity of the plasma may be degraded or a seal member of the gate value may be deteriorated by the plasma. To solve this problem, the openings of the chamber and the deposition shield are designed to be shut by a shutter. A driving unit for the shutter is provided under the openings, for example, and the shutter is opened and closed by being driven by the driving unit.

Patent Document 1: Japanese Patent Laid-open Publication No. 2011-171763

Patent Document 2: Japanese Patent Laid-open Publication No. 2000-031106

In the technology as described above, however, a gap between the deposition shield and the shutter is straightly extended up to the inner wall of the chamber, when viewed from a cross section of the shutter in a thickness direction thereof. Accordingly, in case that the ions or the like generated within the chamber enter the gap, the ions of the like may not be deactivated until it reaches the inner wall of the chamber, so that an abnormal discharge occurs at the inner wall of the chamber.

### SUMMARY

In one example embodiment, a substrate processing apparatus includes a cylindrical chamber having a first opening through which a processing target substrate is loaded into the chamber; a protection member which is provided along an inner wall of the chamber and has a second opening at a position corresponding to the first opening; and an opening/closing member, having a plate shape, configured to open and close the second opening. Further, in a state that the second opening is closed by the opening/closing member, an outer periphery of the opening/closing member is overlapped with the protection member in a thickness direction of the opening/closing member, and an inner periphery of the second opening is overlapped with the opening/closing member in the thickness direction of the opening/closing member.

In the example embodiment, a substrate processing apparatus includes a cylindrical chamber having a first opening through which a processing target substrate is loaded into the chamber; a protection member which is provided along an inner wall of the chamber and has a second opening at a position corresponding to the first opening; and an opening/closing member, having a plate shape, configured to open and close the second opening. Further, in a state that the second opening is closed by the opening/closing member, an outer periphery of the opening/closing member is overlapped with the protection member in a thickness direction of the opening/closing member, and an inner periphery of the second opening is overlapped with the opening/closing member in the thickness direction of the opening/closing member. a substrate processing apparatus includes a cylindrical chamber having a first opening through which a processing target substrate is loaded into the chamber; a protection member which is provided along an inner wall of the chamber and has a second opening at a position corresponding to the first opening; and an opening/closing member, having a plate shape, configured to open and close the second opening. Further, in a state that the second opening is closed by the opening/closing member, an outer periphery of the opening/closing member is overlapped with the protection member in a thickness direction of the opening/closing member, and an inner periphery of the second opening is overlapped with the opening/closing member in the thickness direction of the opening/closing member.

In the state that the second opening is closed by the opening/closing member, a width of a gap between the outer periphery of the opening/closing member and the inner periphery of the second opening, when seen from a surface of the opening/closing member opposite to a surface thereof at a side of the first opening, may be equal to or less than 1.10 mm.

In the state that the second opening is closed by the opening/closing member, a width of a gap between an outer periphery of an upper end portion of the opening/closing member and an inner periphery of an upper end portion of the second opening, when seen from a surface of the opening/closing member opposite to a surface thereof at a side of the first opening, may be equal to or less than 1.00 mm. Further, a width of a gap between an outer periphery of a left end portion of the opening/closing member and an inner periphery of a left end portion of the second opening, and a width of a gap between an outer periphery of a right end portion of the opening/closing member and an inner periphery of a right end portion of the second opening, when seen from the surface of the opening/closing member opposite to the surface thereof at the side of the first opening, may be equal to or less than 0.80 mm, respectively.

The substrate processing apparatus may further include a linear guide provided within the chamber. Furthermore, the opening/closing member may open and close the second opening while moving along a path guided by the linear guide.

In another example embodiment, a shutter device that closes an opening through which a substrate is loaded into a space within a plasma processing apparatus and suppresses abnormal discharge in a gap of the opening includes a first member configured to partition the space in which plasma is generated; and a shield member configured to close the opening such that the plasma is not diffused outwardly from the space. Further, the gap formed between the first member and the shield member is controlled to be in a range within which the abnormal discharge does not occur in the gap.

The gap may be formed such that the first member and the shield member are overlapped with each other in a thickness direction of the shield member.

A width of the gap at an upper end portion of the shield member may be equal to or less than 1.00 mm, and widths of the gap at a left end portion and a right end portion of the shield member may be equal to or less than 0.80 mm.

The shield member may be configured to close the opening by moving along a path guided by a linear guide provided in the plasma processing apparatus.

In yet another example embodiment, a plasma processing apparatus includes a chamber having a space into which a substrate is loaded; and a shutter device configured to close an opening of the chamber. Further, the shutter device includes a first member configured to partition the space, in which plasma is generated, along an inner sidewall of the chamber; and a shield member configured to close the opening such that the plasma is not diffused outwardly from the space. Furthermore, in a state that the opening is shut by the shield member, a gap formed between the first member and the shield member is controlled to be in a range within which abnormal discharge does not occur in the gap.

The gap may be formed such that the first member and the shield member are overlapped with each other in a thickness direction of the shield member.

A width of the gap at an upper end portion of the shield member may be equal to or less than 1.00 mm. Further, widths of the gap at a left end portion and a right end portion of the shield member may be equal to or less than 0.80 mm.

The shield member may be configured to close the opening by moving along a path guided by a linear guide.

The substrate processing apparatus in accordance with the example embodiments can suppress the abnormal discharge from occurring within the chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a cross sectional view illustrating a schematic configuration of a substrate processing apparatus in accordance with a first example embodiment;

FIG. 2 is an enlarged cross sectional view illustrating a schematic configuration in the vicinity of an upper electrode of FIG. 1;

FIG. 3 is a perspective view schematically illustrating an example shape of a deposition shield;

FIG. 4 is an enlarged view illustrating an example configuration in the vicinity of a shutter;

FIG. 5 is a diagram illustrating a state in which the shutter closes an opening of the deposition shield;

FIG. 6 is a cross sectional view illustrating an example of a cross section taken along a line A-A of FIG. 5;

FIG. 7 is a cross sectional view illustrating an example of a cross section taken along a line B-B of FIG. 5;

FIG. 8 is a diagram for describing a position of a gap between the shutter and the deposition shield when the opening of the deposition shield is closed by the shutter;

FIG. 9 is a table showing example experiment results when investigating occurrence of an abnormal discharge while varying a width of the gap between the shutter and the deposition shield;

FIG. 10 is an enlarged view illustrating an example configuration in the vicinity of a shutter in accordance with a second example embodiment;

FIG. 11 is a cross sectional view illustrating an example of a cross section taken along a line C-C of FIG. 10;

FIG. 12 is a schematic diagram illustrating an example state in which the shutter is opened;

FIG. 13 is a schematic diagram illustrating an example state in which the shutter is opened; and

FIG. 14 is a cross sectional view illustrating a modification example of a guide member.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a substrate processing apparatus in accordance with example embodiments will be described in detail with reference to the accompanying drawings, which form a part of the description. However, it should be noted that the example embodiments are not limiting and the various embodiments can be appropriately combined without departing from the scope of the present disclosure.

### FIRST EXAMPLE EMBODIMENT

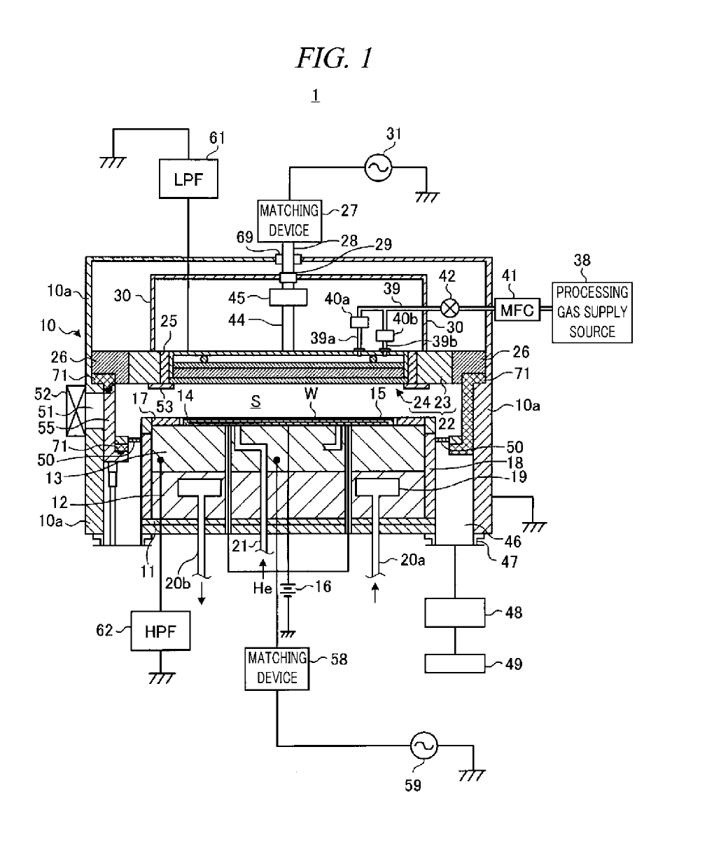

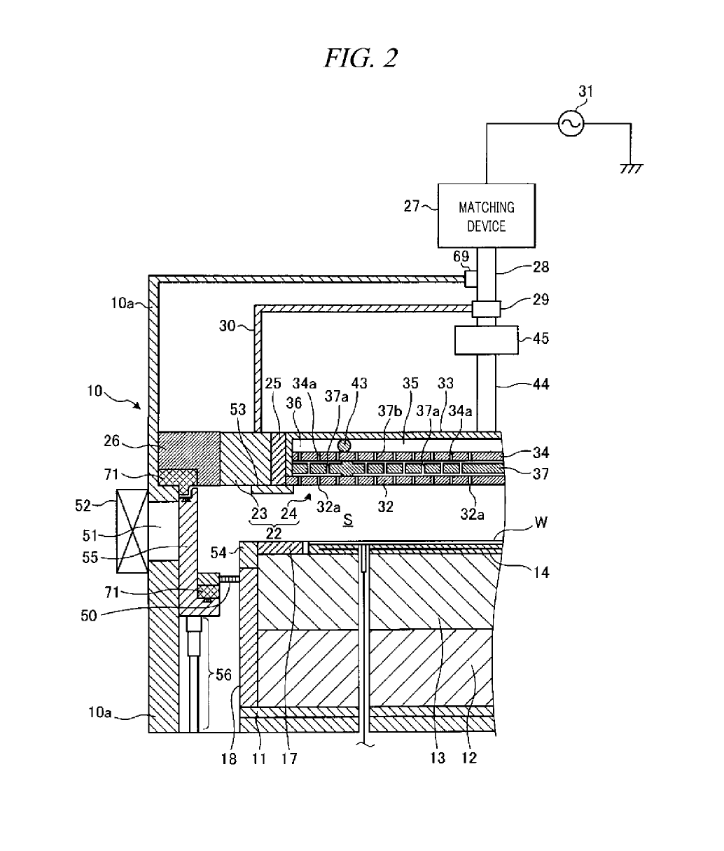

FIG. 1 is a cross sectional view illustrating a schematic configuration of a substrate processing apparatus in accordance with a first example embodiment. FIG. 2 is an enlarged cross sectional view illustrating a schematic configuration of the vicinity of an upper electrode of FIG. 1. The following description is provided for an example case where the substrate processing apparatus is configured as a plasma processing apparatus. However, the example embodiment is not limited thereto and may be applicable to any of various substrate processing apparatuses having a shutter member.

In FIG. 1, a plasma processing apparatus 1 is configured as a capacitively coupled parallel plate type plasma etching apparatus and includes a cylindrical chamber (processing chamber) 10 made of, by way of example, but not limitation, aluminum having an alumite-treated (anodically oxidized) surface. The chamber 10 is frame-grounded. Here, however, the plasma processing apparatus 1 may be any of various types of plasma processing apparatuses such as ICP (Inductively Coupled Plasma) type, a microwave plasma type, a magnetron plasma type, and so forth, without limited to the capacitively coupled parallel plate type plasma etching apparatus.

A cylindrical susceptor supporting member 12 is provided on a bottom portion of the chamber 10 with an insulating plate 11 such as ceramic provided therebetween. A susceptor 13 made of a conductive material such as aluminum is provided on the susceptor supporting member 12. The susceptor 13 serves as a lower electrode and is configured to mount thereon a substrate, such as, but not limited to, a semiconductor wafer W, on which an etching process is to be performed.

An electrostatic chuck (ESC) 14 configured to attract and hold the semiconductor wafer W by an electrostatic attracting force is provided on a top surface of the susceptor 13. The electrostatic chuck 14 includes a pair of insulating layers made of a dielectric material such as, but not limited to, Y₂O₃, Al₂O₃ or AlN; and an electrode plate 15 made of a conductive film and embedded between the pair of insulating layers. The electrode plate 15 is electrically connected to a DC power supply 16 via a connecting terminal. The electrostatic chuck 14 is configured to attract and hold the semiconductor wafer W by a Coulomb force or a Johnsen-Rahbek force generated by a DC voltage applied from the DC power supply 16.

Further, multiple (e.g., three) pusher pins as lift pins capable of being protruded from a top surface of the electrostatic chuck 14 are arranged at a region of the top surface of the electrostatic chuck 14 on which the semiconductor wafer W is held. These are connected to a motor (not shown) by ball screws (not shown). Thus, since a rotary motion of the motor is converted into a linear motion by the ball screws, the pusher pins can be protruded from the top surface of the electrostatic chuck 14. The pusher pins penetrate the electrostatic chuck 14 and the susceptor 13 and are vertically moved through a space inside them to be protruded from or retracted into the space. In case of performing an etching process on the semiconductor wafer W, the pusher pins are accommodated in the electrostatic chuck 14 when the electrostatic chuck 14 attracts and holds the semiconductor wafer W, whereas the pusher pins are protruded from the electrostatic chuck 14 to lift up the semiconductor wafer W away from the electrostatic chuck 14 when the processed semiconductor wafer W after the etching process is unloaded from a plasma generation space S.

To improve uniformity in the etching process, a focus ring 17 made of, for example, silicon (Si) is provided on a peripheral portion of the top surface of the susceptor 13, and a cover ring 54 configured to cover a side surface of the focus ring 17 is provided around the focus ring 17. Further, side surfaces of the susceptor 13 and the susceptor supporting member 12 are covered by a cylindrical member 18 made of, for example, quartz (SiO₂).

A coolant path 19 extended in, e.g., a circumferential direction is provided within the susceptor supporting member 12. A coolant of a preset temperature, e.g., cooling water from an external chiller unit (not shown) is supplied into and circulated through the coolant path 19 via pipelines 20a and 20b. A processing temperature of the semiconductor wafer W on the susceptor 13 can be controlled by adjusting the temperature of the coolant within the coolant path 19.

Further, a heat transfer gas, e.g., a He gas from a heat transfer gas supplying device (not shown) is supplied into a gap between the top surface of the electrostatic chuck 14 and a rear surface of the semiconductor wafer W through a gas supply line 21. Accordingly, heat transfer between the semiconductor wafer W and the susceptor 13 can be efficiently controlled to be uniform.

An upper electrode 22 is provided above the susceptor 13, facing the susceptor 13 in parallel. Here, a space formed between the susceptor 13 and the upper electrode 22 serves as the plasma generation space S (in-chamber space). The upper electrode 22 includes an annular or donut-shaped outer upper electrode 23; and a circular plate-shaped inner upper electrode 24 provided inside the outer upper electrode 23 in a radial direction. Here, the outer upper electrode 23 and the inner upper electrode 24 are arranged with a preset gap, and the inner upper electrode 24 is electrically insulated from the outer upper electrode 23. The outer upper electrode 23 mainly contributes to plasma generation, and the inner upper electrode 24 additionally contributes to the plasma generation.

As depicted in FIG. 2, an annular gap (minute gap) ranging from, for example, 0.25 mm to 2.0 mm is formed between the outer upper electrode 23 and the inner upper electrode 24. A dielectric member 25 made of, but not limited to, quartz is disposed within the gap. Alternatively, a ceramic member may be disposed within the gap instead of the dielectric member 25. With the dielectric member 25 between the outer upper electrode 23 and the inner upper electrode 24, a capacitor is formed. A capacitance C1 of the capacitor is selected or adjusted to a required value by controlling a size of the gap and a relative permittivity of the dielectric member 25. Further, an annular insulating shield member 26 made of, but not limited to, alumina (Al₂O₃) or yttria (Y₂O₃) is provided between the outer upper electrode 23 and a sidewall of the chamber 10 hermetically.

It may be desirable that the outer upper electrode 23 is composed of a semiconductor or a conductor having a low-resistance and a low Joule heat, e.g., silicon. The outer upper electrode 23 is electrically connected to an upper high frequency power supply 31 via an upper matching device 27, an upper power feed rod 28, a connector 29 and a power feeder 30. The upper high frequency power supply 31 outputs a high frequency voltage of a frequency equal to or higher than 13.5 MHz, e.g., 60 MHz. The upper matching device 27 serves to match a load impedance to an internal (or output) impedance of the upper high frequency power supply 31 and can control the output impedance of the upper high frequency power supply 31 and the load impedance thereof to be apparently matched with each other when plasma is generated in the chamber 10. Further, an output terminal of the upper matching device 27 is connected to an upper end of the upper power feed rod 28.

The power feeder 30 is made of a conductive plate such as an aluminum plate or a copper plate having a substantially cylindrical or conical shape. A lower end of the power feeder 30 is connected to the outer upper electrode 23 along the whole circumference thereof, and an upper end of the power feeder 30 is electrically connected to a lower end of the upper power feed rod 28 via the connector 29. Outside the power feeder 30, the sidewall of the chamber 10 is extended upward to a position higher than the upper electrode 22 to form a cylindrical grounding conductor 10a. An upper end of the cylindrical grounding conductor 10a is electrically insulated from the upper power feed rod 28 by a cylindrical insulating member 69. With the present configuration, a coaxial line is formed by the power feeder 30, the outer upper electrode 23 and the grounding conductor 10a in a load circuit with respect to the connector 29. Here, the power feeder 30 and the outer upper electrode 23 serve as a waveguide.

The inner upper electrode 24 includes an upper electrode plate 32 having a multiple number of electrode plate gas through holes 32a (first gas through holes) and made of a semiconductor material such as, but not limited to, silicon or silicon carbide (SiC); an electrode supporting body 33 made of a conductive material such as aluminum having an alumite-treated surface and configured to support the upper electrode plate 32 in a detachable manner. The upper electrode plate 32 is fastened to the electrode supporting body 33 through bolts (not shown). Head portions of the bolts are protected by an annular shield ring 53 provided under the upper electrode plate 32.

Each electrode plate gas through hole 32a is formed over the upper electrode plate 32. Provided within the electrode supporting body 33 is a buffer room into which a processing gas to be described later is introduced. The buffer room includes two buffer rooms divided by an annular partition wall member 43 made of, but not limited to an O-ring: a central buffer room 35 and a peripheral buffer room 36. A bottom of the buffer room is open. A cooling plate (hereinafter, referred to as ‘C/P’) 34 (intermediate member) configured to close the bottom of the buffer room is provided under the electrode supporting body 33. The C/P 34 is made of aluminum having an alumite-treated surface and has many C/P gas through holes 34a (second gas through holes). Each C/P gas through hole 34a is formed over the C/P 34.

Further, a spacer 37 made of a semiconductor material such as silicon or silicon carbide is provided between the upper electrode plate 32 and the C/P 34. The spacer 37 is a circular plate-shaped member and has, on its surface facing the C/P 34 (hereinafter, referred to as “top surface”), a multiple number of top surface annular grooves 37b formed to be concentric with the circular plate; and a multiplicity of spacer gas through holes 37a (third gas through holes) which are opened at bottoms of the respective top surface annular grooves 37b and formed through the spacer 37.

The inner upper electrode 24 supplies a processing gas, which is introduced into the buffer room from a processing gas supply source 38 to be described later, into the plasma generation space S via the C/P gas through holes 34a of the C/P 34, a spacer gas path of the spacer 37 and the electrode plate gas through holes 32a of the upper electrode plate 32. Here, the central buffer room 35, the multiple C/P gas through holes 34a, the spacer gas path and the electrode plate gas through holes 32a arranged under the central buffer room 35 constitute a central shower head (processing gas supply path), whereas the peripheral buffer room 36, multiple C/P gas through holes 34a, the spacer gas path and the electrode plate gas through holes 32a arranged under the peripheral buffer room 36 constitute a peripheral shower head (processing gas supply path).

Further, as depicted in FIG. 1, the processing gas supply source 38 is provided outside the chamber 10. The processing gas supply source 38 is configured to supply a processing gas into the central buffer room 35 and the peripheral buffer room 36 at a certain flow rate ratio. To elaborate, a gas supply line 39 from the processing gas supply source 38 is branched into two branch lines 39a and 39b, which are connected to the central buffer room 35 and the peripheral buffer room 36, respectively. The branch lines 39a and 39b are equipped with flow rate control valves 40a and 40b (flow rate controllers), respectively. Since conductance of a path from the processing gas supply source 38 to the central buffer room 35 and conductance of a path from the processing gas supply source 38 to the peripheral buffer room 36 are set to be same, it is possible to control the flow rate ratio of the processing gases supplied into the central buffer room 35 and the peripheral buffer room 36 individually by adjusting the flow rate control valves 40a and 40b. Further, at the gas supply line 39, a mass flow controller (MFC) 41 and an opening/closing valve 42 are provided.

With the above-described configuration, the plasma processing apparatus 1 is capable of adjusting a ratio FC/FE between a flow rate FC of the processing gas discharged from the central shower head and a flow rate FE of the processing gas discharged from the peripheral shower head by adjusting flow rates of the processing gases supplied into the central buffer room 35 and the peripheral buffer room 36. Further, it is also possible to adjust flow rates per unit area of the processing gases supplied from the central shower head and the peripheral shower head individually. Furthermore, by providing two processing gas supply sources corresponding to the branch lines 39a and 39b, respectively, it is also possible to set the kinds or the mixing ratio of processing gases supplied from the central shower head and the peripheral shower head individually or separately. However, the example embodiment is not limited thereto, and the plasma processing apparatus 1 may not control the ratio FC/FE between the flow rate FC of the processing gas discharged from the central shower head and the flow rate FE of the processing gas discharged from the peripheral shower head.

The electrode supporting body 33 of the inner upper electrode 24 is electrically connected to the upper high frequency power supply 31 via the upper matching device 27, the upper power feed rod 28, the connector 29 and a upper power feeder 44. A variable capacitor 45 capable of varying a capacitance thereof is provided on a portion of the upper power feeder 44. Further, a coolant path or cooling jacket (not shown) may also be provided within the outer upper electrode 23 and the inner upper electrode 24, so that it is possible to control the temperatures of the electrodes by a coolant supplied from an external chiller unit (not shown).

A gas exhaust opening 46 is formed at a bottom portion of the chamber 10, and an automatic pressure control valve (hereinafter, referred to as “APC” valve) 48, which is a variable butterfly valve, and a turbo molecular pump (hereinafter, referred to as “TMP”) 49 are connected to the gas exhaust opening 46 via a gas exhaust manifold 47. The APC valve 48 and the TMP 49 cooperate to decompress the plasma generation space S within the chamber 10 to a required vacuum degree. Further, an annular baffle plate 50 having a multiple number of gas through holes is provided between the gas exhaust opening 46 and the plasma generation space S to surround the susceptor 13. The baffle plate 50 serves to suppress leakage of plasma from the plasma generation space S into the gas exhaust opening 46.

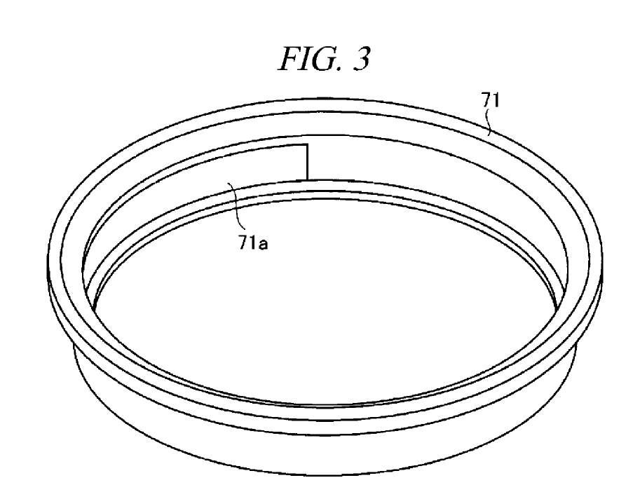

Further, an opening 51 configured to load and unload a semiconductor wafer W is formed in an outer sidewall of the chamber 10, and a gate valve 52 configured to open and close the opening 51 is provided. Within the chamber 10, a substantially cylindrical deposition shield 71 is provided along an inner wall of the chamber 10. FIG. 3 is a perspective view schematically illustrating an example shape of the deposition shield. As shown in FIG. 3, the deposition shield 71 has an opening 71a in a sidewall thereof and is provided within the chamber 10 along the inner wall of the chamber 10 such that the opening 71a communicates with the opening 51 of the chamber 10. The deposition shield 71 serves as a protection member that suppresses etching byproducts (deposits) from adhering to the inner wall of the chamber 10. An inner wall of the substantially cylindrical deposition shield 71 is coated with, by way of non-limiting example, yttria (Y₂O₃) by thermal spraying.

A semiconductor wafer W is loaded into and unloaded from the chamber 10 after the gate valve 52 is opened. Here, since the gate valve 52 is provided outside the chamber 10 (at the atmospheric side), there is formed a space in which the opening 51 is protruded outward. Accordingly, plasma generated within the chamber 10 diffuses up to that space, so that the plasma uniformity may be degraded or a seal member of the gate value 52 may be damaged. As a way to suppress this problem, the opening 71a of the deposition shield 71 is shut off by a shutter 55 to isolate the plasma generation space S and the opening 51 of the chamber 10 from each other. Further, a driving unit configured to drive the shutter 55 may be provided under the deposition shield 71, for example, and the shutter 55 is driven up and down by operating the driving unit 56 so that the opening 71a of the deposition shield 71 can be opened and closed. The deposition shield 71 and the shutter 55 may be referred to as a shutter device.

Further, in the plasma processing apparatus 1, the susceptor 13 serving as the lower electrode is electrically connected to a lower high frequency power supply (first high frequency power supply) 59 via a lower matching device 58. The lower high frequency power supply 59 is configured to output a high frequency voltage of a frequency in the range from 2 MHz to 27 MHz, e.g., 2 MHz. The lower matching device 58 serves to match a load impedance to an internal (or output) impedance of the lower high frequency power supply 59 and can control the output impedance of the lower high frequency power supply 59 and the load impedance thereof to be apparently matched with each other when the plasma is generated in the plasma generation space S of the chamber 10. Further, another second lower high frequency power supply (second high frequency power supply) may also be connected to the lower electrode. In this case, a high frequency voltage of, e.g., 2 MHz may be applied from the first high frequency power supply, and a high frequency voltage of, e.g., 13.56 MHz may be applied from the second high frequency power supply.

Further, in the plasma processing apparatus 1, a low pass filter (LPF) 61 configured to suppress the high frequency power (60 MHz) from the upper high frequency power supply 31 from being flown to the ground while allowing the high frequency power (2 MHz) from the lower high frequency power supply 59 to be flown to the ground is electrically connected to the inner upper electrode 24. Desirably, the LPF 61 may be implemented by a LR filter or a LC filter. Here, however, since even a single conducting wire can apply sufficiently large reactance to the high frequency power from the upper high frequency power supply 31, it may be possible to set up a configuration where a single conducting wire, instead of the LR filter or the LC filter, is electrically connected to the inner upper electrode 24. Meanwhile, a high pass filter (HPF) 62 configured to allow the high frequency power from the upper high frequency power supply 31 to flow to the ground is electrically connected to the susceptor 13.

To perform the etching process in the plasma processing apparatus 1, the gate valve 52 and the shutter 55 are first opened, and a target semiconductor wafer W is loaded into the chamber 10 to be mounted on the susceptor 13. A processing gas, e.g., a mixture gas of a C₄F₈ gas and an argon (Ar) gas is introduced into the central buffer room 35 and the peripheral buffer room 36 from the processing gas supply source 38 at preset flow rates with a preset flow rate ratio, and an internal pressure of the plasma generation space S within the chamber 10 is set to be an appropriate value for the etching process, e.g., a certain value in the range from, e.g., several mTorr to 1 Torr through the APC valve 48 and the TMP 49.

Further, a high frequency power of, e.g., 60 MHz for plasma generation is applied from the upper high frequency power supply 31 to the upper electrode 22 (outer upper electrode 23, inner upper electrode 24) at a preset power level, and a high frequency power of, e.g., 2 MHz for bias is applied from the lower high frequency power supply 59 to the susceptor 13 as the lower electrode at a certain power level. Further, a DC voltage from the DC power supply 16 is applied to the electrode plate 15 of the electrostatic chuck 14, so that the semiconductor wafer W is attracted to and held on the susceptor 13 electrostatically.

Plasma is generated in the plasma generation space S by the processing gas discharged from the shower head, and a processing target surface of the semiconductor wafer W is physically or chemically etched by radicals or ions in the plasma.

In the plasma processing apparatus 1, by applying a high frequency power of a high frequency (e.g., equal to or higher than 5 MHz to 10 MHz at which ions cannot move) to the upper electrode 22, the plasma can be highly densified with a desirable dissociated state. Further, it is also possible to generate the high-density plasma under a lower pressure condition.

Meanwhile, in the upper electrode 22, the outer upper electrode 23 is used as a main high frequency electrode for plasma generation, and the inner upper electrode 24 is used as an additional electrode therefor. An intensity ratio of the electric fields applied to electrons directly under the upper electrode 22 can be adjusted by the upper high frequency power supply 31 and the lower high frequency power supply 59. Accordingly, a spatial distribution of the ion density can be controlled in a radial direction, and spatial characteristics of the reactive ion etching can also be precisely controlled as required.

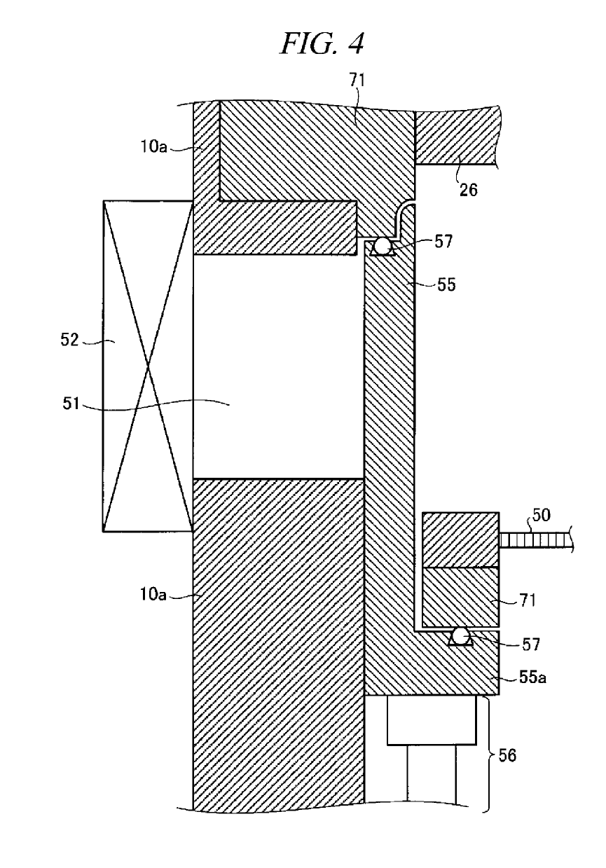

Now, a configuration in the vicinity of the shutter 55 in accordance with the present example embodiment will be explained. FIG. 4 is an enlarged view illustrating an example configuration in the vicinity of the shutter. The shutter 55 is a plate-shaped member configured to open and close the opening 71a of the deposition shield 71. By way of non-limiting example, the shutter 55 is made of aluminum and has a substantially L-shaped cross section. A surface of the shutter 55 is coated with, but not limited to, yttria (Y₂O₃).

Further, as depicted in the cross sectional view of FIG. 4, a spiral 57, which is a conductive elastic member, is provided at an upper end portion of the shutter 55. Further, as shown in FIG. 4, a conductive spiral 57 is also provided at a top surface of an extension portion 55a which is extended toward the plasma generation space S (right side of FIG. 4) at a lower portion of the shutter 55 having the L-shaped cross section.

The driving unit 56 moves up the shutter 55 to close the opening 71a of the deposition shield 71 and the driving unit 56 moves down the shutter 55 to open the opening 71a of the deposition shield 71. With the opening 71a of the deposition shield 71 closed by the shutter 55, the spirals 57 provided at the upper and lower portions of the shutter 55 come into contact with the deposition shield 71, so that the shutter 55 and the deposition shield 71 are electrically connected via the spirals 57. Since the deposition shield 71 is in contact with the grounding conductor 10a of the chamber 10, the shutter 55 is also grounded via the deposition shield 71 while the opening 71a of the deposition shield 71 is closed.

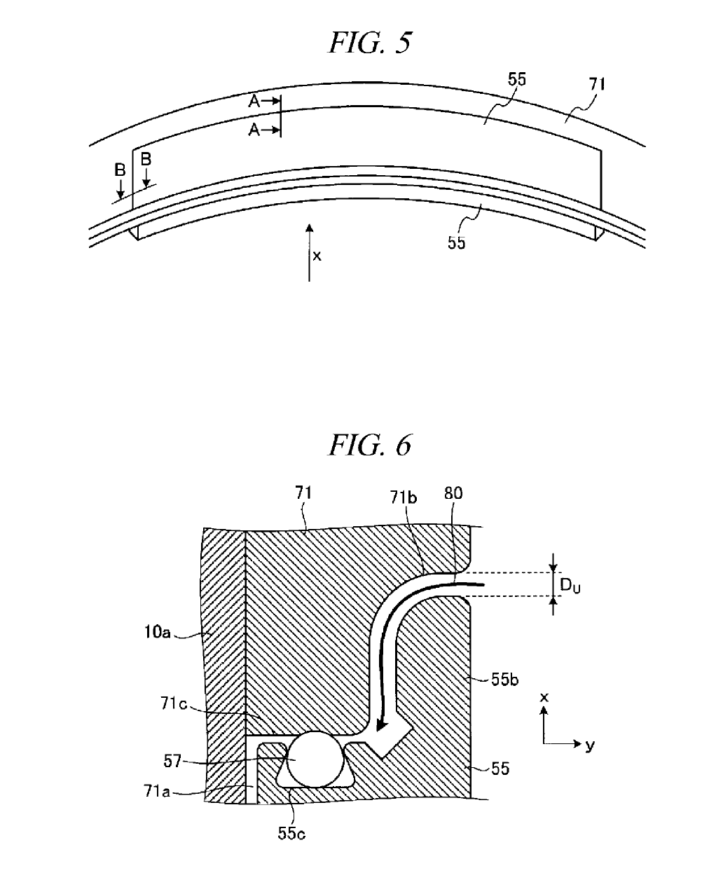

FIG. 5 is a diagram for describing a state in which the shutter closes the opening of the deposition shield. FIG. 5 illustrates the shutter 55 and the deposition shield 71 seen from the plasma generation space S (from inside the deposition shield 71). FIG. 6 is a cross sectional view illustrating an example of a cross section taken along a line A-A of FIG. 5, and FIG. 7 is a cross sectional view illustrating an example of a cross section taken along a line B-B of FIG. 5.

As shown in the cross sectional view of FIG. 6, a protruded portion 55b extended upwardly as compared to a side of the grounding conductor 10a (opposite side to y-direction of FIG. 6) is formed on an upper portion of the shutter 55 at the side of the plasma generation space S (y-direction side) in a thickness direction of the shutter 55. Further, a recessed portion 71b is formed on an upper portion of the opening 71a of the deposition shield 71 at the side of the plasma generation space S in the thickness direction of the shutter 55. The recessed portion 71b is upwardly recessed, as compared to the opening 71a at the side of the grounding conductor 10a. With the opening 71a of the deposition shield 71 closed by the shutter 55, the protruded portion 55b of the shutter 55 faces the recessed portion 71b of the opening 71a of the deposition shield 71.

Furthermore, as depicted in the cross sectional view of FIG. 6, the conductive spiral 57 is provided in a groove 55c formed at the upper end portion of the shutter 55. While the shutter 55 closes the opening 71a of the deposition shield 71, the conductive spiral 57 comes into contact with an upper end surface 71c of the opening 71a of the deposition shield 71. Further, in the state that the shutter 55 closes the opening 71a of the deposition shield 71, there is formed a minute gap between the opening 71a of the deposition shield 71 and the rest of the upper portion of the shutter 55 except where the conductive spiral 57 is provided.

Here, assume that the gap between the shutter 55 and the deposition shield 71 is straightly extended to an inner wall of the grounding conductor 10a of the chamber 10. In such a case, ions or the like generated in the plasma generation space S may enter the gap between shutter 55 and the deposition shield 71 to reach the inner wall of the grounding conductor 10a with high energy. As a result, the abnormal discharge may occur at the inner wall of the grounding conductor 10a. If the abnormal discharge takes place, a portion of the inner wall of the grounding conductor 10a may be peeled off and float within the plasma generation space S, so that the particle contamination may generated. Further, if the abnormal discharge occurs, the plasma energy generated in the plasma generation space S may be decreased through the abnormal discharge, so that the plasma density may be decreased or the plasma uniformity may be deteriorated, resulting in degradation of the etching quality.

In the present example embodiment, however, in the state that the shutter 55 closes the opening 71a of the deposition shield 71, an outer periphery of the upper portion of the shutter 55, i.e., an upper end surface of the protruded portion 55b is overlapped with the deposition shield 71 in the thickness direction of the shutter 55 (y-direction of FIG. 6). Further, an inner periphery of the opening 71a of the deposition shield 71, i.e., an upper end surface 71c of the opening 71a is overlapped with the shutter 55 in the thickness direction of the shutter 55.

With this configuration, in the state that the shutter 55 closes the opening 71a of the deposition shield 71, at least a part of the minute gap between the upper end portion of the shutter 55 and the deposition shield 71 is curved in a different direction from the thickness direction of the shutter 55, forming a so-called labyrinth structure, as shown in the cross sectional view of FIG. 6. Accordingly, even if the ions or the like generated in the plasma generation space S enter the minute gap between the shutter 55 and the deposition shield 71, as indicated by an arrow 80 of FIG. 6, for example, the ions may be deactivated by being diffusely reflected on the surface of the shutter 55 or the surface of the deposition shield 71. Therefore, it is possible to suppress the abnormal discharge from occurring at the inner wall of the grounding conductor 10a.

In addition, if it is possible to reduce the amount of ions that enter the minute gap between the shutter 55 and the deposition shield 71 after generated in the plasma generation space S, the amount of ions that reach the inner wall of the grounding conductor 10a with the high energy may also be reduced, so that it is possible to further suppress the abnormal discharge from occurring. In order to reduce the amount of the ions or the like introduced into the minute gap between the shutter 55 and the deposition shield 71 to a preset amount where the abnormal discharge does not occur at the inner wall of the grounding conductor 10a, a width of a gap D_{U} that is formed, when viewed from the plasma generation space S (y-direction side of FIG. 6), between the upper end portion of the shutter 55 and the deposition shield 71 while the shutter 55 closes the opening 71a of the deposition shield 71 needs to be maintained equal to or smaller than a preset value, desirably. A desirable value of the gap D_{U} will be described later.

Further, as illustrated in the cross sectional view of FIG. 7, a protruded portion 55d extended in a planar direction of the shutter 55 (opposite direction to Z-direction of FIG. 7), as compared to a portion of the shutter 55 at the side of the grounding conductor 10a (at the side of the opposite direction to y-direction of FIG. 7) is formed on a left end portion of the shutter 55 at the side of the plasma generation space S (y-direction side of FIG. 7) in the thickness direction of the shutter 55. Further, a recessed portion 71d is formed on a left end portion of the opening 71a of the deposition shield 71 at the side of the plasma generation space S in the thickness direction of the shutter 55. The recessed portion 71d is recessed in the planar direction of the shutter 55 (opposite direction to z-direction of FIG. 7), as compared to the opening 71a at the side of the grounding conductor 10a. With the opening 71a of the deposition shield 71 closed by the shutter 55, the protruded portion 55d of the shutter 55 faces the recessed portion 71d of the opening 71a of the deposition shield 71.

Further, in the state that the shutter 55 closes the opening 71a of the deposition shield 71, there is formed a minute gap between the left end portion of the shutter 55 and the deposition shield 71. In the present example embodiment, with regard to the positional relationship between the left end portion of the shutter 55 and the left end portion of the opening 71a of the deposition shield 71, an outer periphery of the left end portion of the shutter 55, i.e., a left end surface of the protruded portion 55d is overlapped with the deposition shield 71 in the thickness direction of the shutter 55 while the shutter 55 closes the opening 71a of the deposition shield 71. Also, an inner periphery of the opening 71a of the deposition shield 71, i.e., a left end surface 71e of the opening 71a is overlapped with the shutter 55 in the thickness direction of the shutter 55.

With this configuration, in the state that the shutter 55 closes the opening 71a of the deposition shield 71, at least a part of the minute gap between the left end portion of the shutter 55 and the opening 71a of the deposition shield 71 is curved in a different direction from the thickness direction of the shutter 55, forming a so-called labyrinth structure, as shown in the cross sectional view of FIG. 7. Accordingly, even if the ions or the like generated in the plasma generation space S enter the minute gap between the shutter 55 and the deposition shield 71, as indicated by an arrow 81 of FIG. 7, for example, the ions may be deactivated by being diffusely reflected on the surface of the shutter 55 or the surface of the deposition shield 71. Therefore, it is possible to suppress the abnormal discharge from occurring at the inner wall of the grounding conductor 10a.

Here, by controlling a width of a gap D_{S} between the left end portion of the shutter 55 and the left end portion of the opening 71a of the deposition shield 71 to be equal to or smaller than a preset value, the abnormal discharge at the inner wall of the grounding conductor 10a can be further suppressed. A desirable value of the gap D_{S} will be described later.

A right end portion of the shutter 55 and a right end portion of the opening 71a of the deposition shield 71 have the substantially same structure as the left end portion of the shutter 55 and the left end portion of the opening 71a of the deposition shield 71 excepting that left and right directions are reversed. Thus, it is possible to suppress the abnormal discharge at the inner wall of the grounding conductor 10a from occurring in a gap between the right end portion of the shutter 55 and the opening 71a of the deposition shield 71 as well.

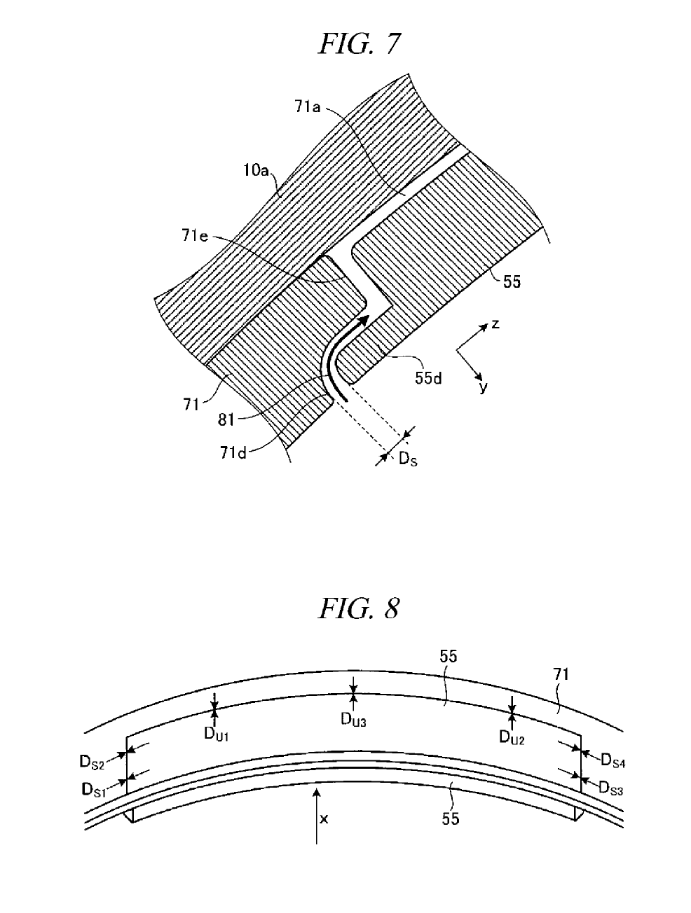

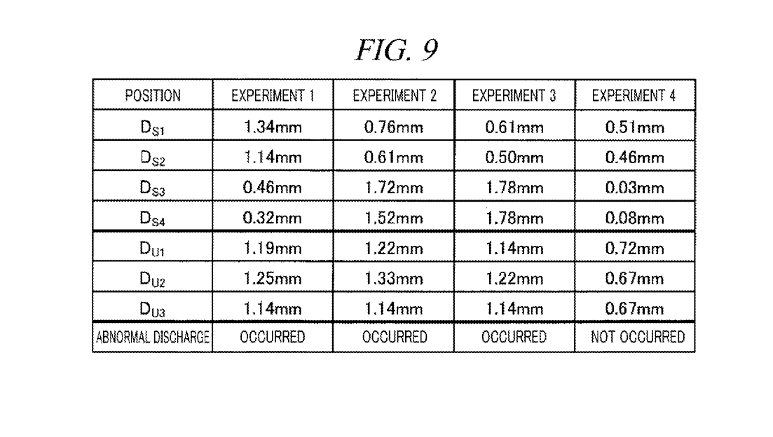

Now, experiment results of investigating the presence or absence of the abnormal discharge while varying the gap between the shutter 55 and the deposition shield 71 will be explained. FIG. 8 is a diagram for describing a position of the gap between the shutter and the deposition shield when the shutter closes the opening of the deposition shield. FIG. 9 is a diagram showing an example experiment result of investigating the presence or absence of the abnormal discharge while varying a width of the gap between the shutter and the deposition shield.

In the experiments, as shown in FIG. 8, in the state that the shutter 55 closed the opening 71a of the deposition shield 71, the presence or absence of the abnormal discharge was investigated while varying widths of gaps D_{S1} and D_{S2} at the left end, D_{S3} and D_{S4} at the right end, and D_{U1} to D_{U3} at the upper end of the shutter 55, respectively.

As depicted in FIG. 9, the abnormal discharge occurred in the gaps between the shutter 55 and the deposition shield 71 in all of experiments 1 to 3. In experiment 4, however, the abnormal discharge did not occur in the gaps between the shutter 55 and the deposition shield 71. From the result of the experiment 4, it was found out that the abnormal discharge did not occur when the maximum of the widths of the gaps D_{S1} to D_{S4} between the left and right end portions of the shutter 55 and the deposition shield 71 was equal to or less than 0.51 mm. Further, it was also found out from the result of the experiment 4 that the abnormal discharge did not occur when the maximum of the widths of the gaps D_{U1} to D_{U3} between the upper end portions of the shutter 55 and the deposition shield 71 was equal to or less than 0.72 mm

The present inventor repeated more experiments and found out that it is possible to suppress the abnormal discharge from occurring when the maximum of the widths of the gaps D_{S1} to D_{S4} and D_{U1} to D_{U3} between the shutter 55 and the deposition shield 71 was set to be equal to or less than 1.10 mm. Thus, it may be desirable to adjust the positional relationship between the shutter 55 and the deposition shield 71 such that the maximum of the widths of the gaps between the left and right end portions of the shutter 55 and the deposition shield 71 and the widths of the gaps between the upper end portion of the shutter 55 and the deposition shield 71 is equal to or less than 1.10 mm.

Further, the present inventor conducted more researches and found that it is possible to further suppress the abnormal discharge from occurring when the maximum of the widths of the gaps D_{U1} to D_{U3} between the upper end portions of the shutter 55 and the deposition shield 71 was equal to or less than 1.00 mm. Thus, it may be desirable to adjust the positional relationship between the shutter 55 and the deposition shield 71 such that the maximum of the widths of the gaps between the upper end portions of the shutter 55 and the deposition shield 71 is equal to or less than 1.00 mm. The widths of the gaps between the upper end portions of the shutter 55 and the deposition shield 71 can be set by adjusting, by way of non-limiting example, a lifting amount of the shutter 55 by the driving unit 56, a size or a repulsive force of the spiral 57 provided at the upper end portion of the shutter 55, and the like.

Further, the present inventor conducted further researches and found out that it is possible to further suppress the abnormal discharge from occurring when the maximum of the widths of the gaps D_{S1} to D_{S4} between the left and right end portions of the shutter 55 and the deposition shield 71 is equal to or less than 0.80 mm. Thus, it may be desirable to adjust the positional relationship between the shutter 55 and the deposition shield 71 such that the maximum of the widths of the gaps between the left and right end portions of the shutter 55 and the deposition shield 71 is equal to or less than 0.80 mm.

In the above, the first example embodiment has been described. In the plasma processing apparatus 1 in accordance with the first example embodiment, the abnormal discharge in the gaps between the deposition shield 71 and the shutter 55 can be suppressed. Therefore, it is possible to suppress the density and uniformity of the plasma generated in the plasma generation space S from being degraded, so that the accuracy degree of the etching process can be improved.

### SECOND EXAMPLE EMBODIMENT

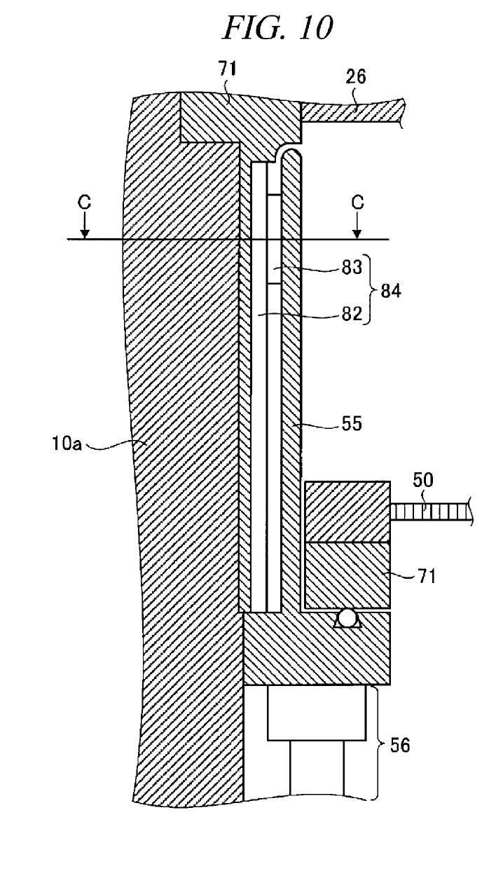

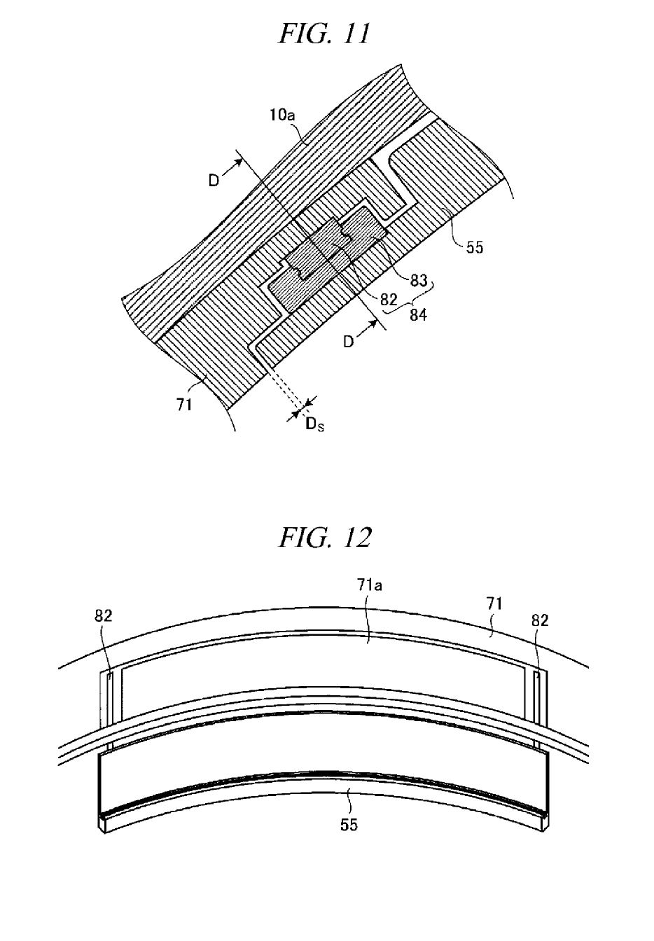

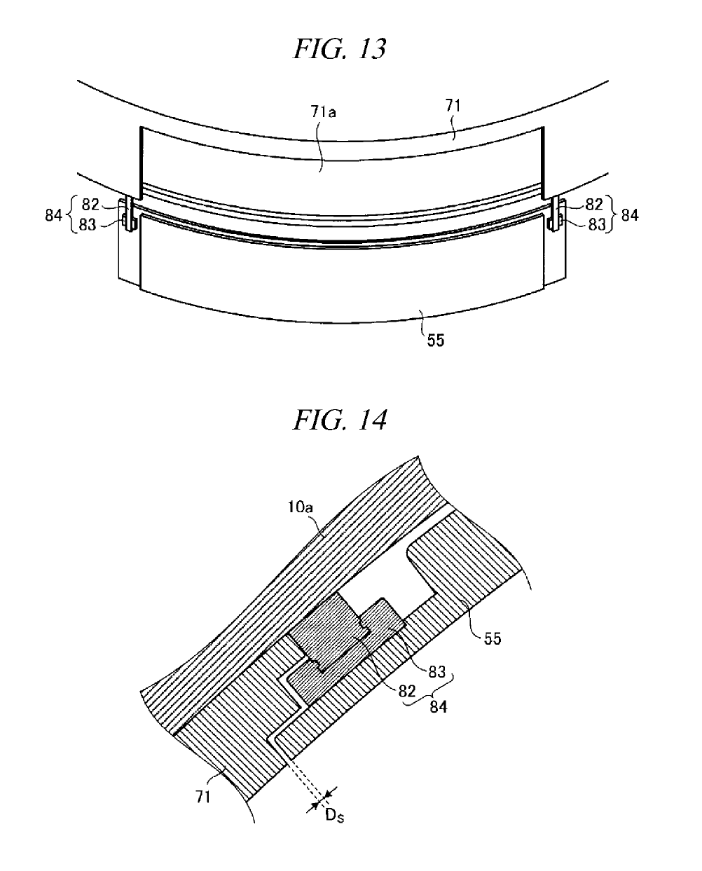

Now, a second example embodiment will be described. Here, description of the same parts as in the first example embodiment will be omitted, and only distinctive parts will be elaborated. FIG. 10 is an enlarged view illustrating an example configuration in the vicinity of a shutter in the second example embodiment. FIG. 11 is a cross sectional view illustrating an example of a cross section taken along a line C-C of FIG. 10. FIG. 12 is a schematic diagram illustrating an example of a state in which the shutter is opened, when seen from the inside of a deposition shield 71. FIG. 13 is a schematic diagram illustrating an example of a state in which the shutter is opened, when seen from the outside of the deposition shield 71. FIG. 10 illustrates an example of a cross section taken along a line D-D of FIG. 11.

In the present example embodiment, guide members 84 are provided between the shutter 55 and the deposition shield 71. Each guide member 84 has a guide rail 82; and a slider 83 configured to be moved along the guide rail 82. The guide rails 82 are provided on both sides of the opening 71a of the deposition shield 71, as depicted in FIG. 12, for example. Further, as shown in FIG. 11 and FIG. 12, the guide rails 82 may be fastened by screws or the like to regions of the deposition shield 71 overlapped with the shutter 55 in a thickness direction of the deposition shield 71 in the state that the shutter 55 closes the opening 71a of the deposition shield 71.

The sliders 83 are provided on both sides of the shutter 55, as depicted in FIG. 13, for example. Further, as shown in FIG. 11 and FIG. 13, the sliders 83 are fastened by screws or the like to the regions of the shutter 55 overlapped with the deposition shield 71 in the thickness direction of the shutter 55 in the state that the shutter 55 closes the opening 71a of the deposition shield 71. By adjusting the fastening position of the guide rails 82 to the deposition shield 71, it is possible to adjust a gap D_{S} that exists between the shutter 55 and the deposition shield 71 in the state that the shutter 55 closes the opening 71a of the deposition shield 71.

The shutter 55 is moved upward with the slider 83 along the guide rails 82 when it is lifted up by the driving unit 56. Accordingly, the guide members 84 are capable of improving the positional accuracy of the shutter 55 in the state that the shutter 55 closes the opening 71a of the deposition shield 71. Thus, the gap D_{S} between the shutter 55 and the deposition shield 71 with the shutter 55 closing the opening 71a of the deposition shield 71 can be maintained equal to or less than a preset value by the guide members 84.

If it is attempted to achieve, only by the driving unit 56, the positional accuracy of the shutter 55 in a planar direction thereof in the state that the opening 71a of the deposition shield 71 is closed, a device configured to conduct a high-precision position adjustment needs to be additionally provided. In the present example embodiment, however, since the width of the gap D_{S} between the shutter 55 and the deposition shield 71 is adjusted by using the guide members 84, it is not required to provide an additional device configured to control the width of the gap D_{S} to the driving unit 56. Therefore, it is possible to suppress overall cost of the plasma processing apparatus 1 from being increased. Furthermore, in the present example embodiment, since the guide rails 82 are attached to the deposition shield 71, the burden of providing the guide rails 82 can be reduced.

### MODIFICATION EXAMPLE

FIG. 14 is a cross sectional view illustrating a modification example of the guide member. The guide rail 82 may be fastened to the inner wall of the grounding conductor 10a of the chamber 10 by screws or the like, as depicted in FIG. 14. In this modification example, in order to fasten the guide rail 82 to the inner wall of the grounding conductor 10a, a large space may be obtained for providing the guide member 84. Accordingly, the guide rail 82 and the slider 83 may have sizes larger than the guide rail 82 and the slider 83 in the second example embodiment. Thus, manufacturing cost of the guide rail 82 and the slider 83 can be reduced, so that it is possible to suppress the overall cost of the plasma processing apparatus 1 from being increased.

Other inventive effects or modification examples may be easily conceived by those skilled in the art. From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A substrate processing apparatus, comprising:
a cylindrical chamber having a first opening through which a processing target substrate is loaded into the chamber;
a protection member which is provided along an inner wall of the chamber and has a second opening at a position corresponding to the first opening; and
an opening/closing member, having a plate shape, configured to open and close the second opening,
wherein, in a state that the second opening is closed by the opening/closing member, an outer periphery of the opening/closing member is overlapped with the protection member in a thickness direction of the opening/closing member, and an inner periphery of the second opening is overlapped with the opening/closing member in the thickness direction of the opening/closing member.

2. The substrate processing apparatus of claim 1,
wherein, in the state that the second opening is closed by the opening/closing member,
a width of a gap between the outer periphery of the opening/closing member and the inner periphery of the second opening, when seen from a surface of the opening/closing member opposite to a surface thereof at a side of the first opening, is equal to or less than 1.10 mm.

3. The substrate processing apparatus of claim 1,
wherein, in the state that the second opening is closed by the opening/closing member,
a width of a gap between an outer periphery of an upper end portion of the opening/closing member and an inner periphery of an upper end portion of the second opening, when seen from a surface of the opening/closing member opposite to a surface thereof at a side of the first opening, is equal to or less than 1.00 mm, and
a width of a gap between an outer periphery of a left end portion of the opening/closing member and an inner periphery of a left end portion of the second opening, and a width of a gap between an outer periphery of a right end portion of the opening/closing member and an inner periphery of a right end portion of the second opening, when seen from the surface of the opening/closing member opposite to the surface thereof at the side of the first opening, are equal to or less than 0.80 mm, respectively.

4. The substrate processing apparatus of claim 1, further comprising:
a linear guide provided within the chamber,
wherein the opening/closing member opens and closes the second opening while moving along a path guided by the linear guide.

5. A shutter device that closes an opening through which a substrate is loaded into a space within a plasma processing apparatus and suppresses abnormal discharge in a gap of the opening, the shutter device comprising:
a first member configured to partition the space in which plasma is generated; and
a shield member configured to close the opening such that the plasma is not diffused outwardly from the space,
wherein the gap formed between the first member and the shield member is controlled to be in a range within which the abnormal discharge does not occur in the gap.

6. The shutter device of claim 5,
wherein the gap is formed such that the first member and the shield member are overlapped with each other in a thickness direction of the shield member.

7. The shutter device of claim 5,
wherein a width of the gap at an upper end portion of the shield member is equal to or less than 1.00 mm, and
widths of the gap at a left end portion and a right end portion of the shield member are equal to or less than 0.80 mm.

8. The shutter device of claim 5,
wherein the shield member is configured to close the opening by moving along a path guided by a linear guide provided in the plasma processing apparatus.

9. A plasma processing apparatus comprising:
a chamber having a space into which a substrate is loaded; and
a shutter device configured to close an opening of the chamber,
wherein the shutter device comprises:
a first member configured to partition the space, in which plasma is generated, along an inner sidewall of the chamber; and
a shield member configured to close the opening such that the plasma is not diffused outwardly from the space,
wherein, in a state that the opening is shut by the shield member, a gap formed between the first member and the shield member is controlled to be in a range within which abnormal discharge does not occur in the gap.

10. The plasma processing apparatus of claim 9,
wherein the gap is formed such that the first member and the shield member are overlapped with each other in a thickness direction of the shield member.

11. The plasma processing apparatus of claim 9,
wherein a width of the gap at an upper end portion of the shield member is equal to or less than 1.00 mm, and
widths of the gap at a left end portion and a right end portion of the shield member are equal to or less than 0.80 mm.

12. The plasma processing apparatus of claim 9,
wherein the shield member is configured to close the opening by moving along a path guided by a linear guide.
